(19) United States
(12) Patent Application Publication
(10) Pub. No.: US 2012/0201953 A1
(43) Pub. Date: Aug. 9, 2012

(54) CONDUCTIVE SUBSTRATE, MANUFACTURING METHOD OF CONDUCTIVE SUBSTRATE, AND LASER LIGHT IRRADIATION DEVICE

(75) Inventors: Katsuji Takagi, Kanagawa (JP); Yuichi Aki, Tokyo (JP)

(73) Assignee: SONY CORPORATION, Tokyo (JP)

(21) Appl. No.: 13/360,160

(22) Filed: Jan. 27, 2012

(30) Foreign Application Priority Data
Feb. 3, 2011 (JP) 2011-021634

(51) Int. Cl. C23C 16/52; B32B 3/00

(52) U.S. Cl. 427/8; 118/676; 428/195.1

(57) ABSTRACT

A conductive substrate includes substrate made of a resin material, and a conductive layer formed on the substrate by baking a conductive paste which is coated on the substrate at a predetermined position, wherein the conductive layer is formed through baking by applying second laser light to the conductive paste of which a position on the substrate is detected based on a difference in reflectance depending on the application positions of first laser light applied to the substrate.

### CROSS REFERENCES TO RELATED APPLICATIONS

The present application claims priority to Japanese Priority Patent Application JP 2011-021634 filed in the Japan Patent Office on Feb. 3, 2011, the entire content of which is hereby incorporated by reference.

### BACKGROUND

The present disclosure relates to a conductive substrate, a manufacturing method of the conductive substrate, and a laser light irradiation device. Specifically, the present disclosure relates to a technical field which improves a degree of freedom regarding selection of materials of the substrate by performing both a position detection of a conductive paste on the substrate and baking of the conductive paste through irradiation of laser light.

Conductive substrates provided with conductive layers are disposed in a variety of electronic apparatuses.

Among the conductive substrates, there is one where conductive layers are formed on a substrate through, for example, printing (for example, refer to Japanese Unexamined Patent Application Publication No. 2008-205144).

In a method of manufacturing a conductive substrate through printing, a conductive paste, for example, a metal paste is printed at a predetermined position of the substrate, and then undergoes heat treatment for low resistance. The conductive paste is baked by the heat treatment such that unnecessary dispersants contained in the conductive paste are removed and metal particles are bonded to each other, thereby forming conductive layers and securing favorable conductivity.

The heat treatment is performed by inserting and disposing a substrate on which a conductive paste is printed into an oven equal to or more than 200° C.

### SUMMARY

However, as described above, in order to form conductive layers with the heat treatment, it is necessary for the substrate on which the conductive paste is printed to be disposed in the oven equal to or more than 200° C., and thus the substrate which is made of a material having high heat resistance is necessarily used.

Therefore, there is a problem in that it is difficult to use a low price material such as a PET (polyethylene terephthalate) resin having low heat resistance for a substrate, and thus manufacturing costs increase.

It is desirable to provide a conductive substrate, a manufacturing method of the conductive substrate, and a laser light irradiation device which improve a degree of freedom regarding selection of materials of a substrate by overcoming the problem.

According to an embodiment of the present disclosure, there is provided a conductive substrate including a substrate made of a resin material; and a conductive layer formed on the substrate by baking a conductive paste which is coated on the substrate at a predetermined position, wherein the conductive layer is formed through baking by applying second laser light to the conductive paste of which the position on the substrate is detected based on a difference in reflectance depending on the application positions of first laser light applied to the substrate.

Therefore, the second laser light having a light amount necessary for baking is applied only to the conductive paste on the substrate.

In the conductive substrate, a formation state of the conductive layer on the substrate is preferably detected by applying third laser light to the substrate.

A formation state of the conductive layer on the substrate is detected by applying the third laser light to the substrate, and thereby it is possible to change a light amount of the second laser light according to the formation state of the conductive layer.

In the conductive substrate, an application intensity of the second laser light to the conductive paste is preferably varied according to an application time.

By varying the application intensity of the second laser light to the conductive paste according to an application time, it is possible to vary the application intensity of laser light depending on an absorption state of heat of the conductive paste according to the application time of the laser light.

In the conductive substrate, it is preferable that the substrate be moved in a predetermined direction, the position of the conductive paste be detected by varying the application angle of the first laser light to the substrate in a direction perpendicular to the movement direction of the substrate, and the conductive paste be baked by varying the application angle of the second laser light to the substrate in the direction perpendicular to the movement direction of the substrate.

A position of the conductive paste is detected by varying the application angle of the first laser light to the substrate, and the conductive paste is baked by varying the application angle of the second laser light to the substrate, thereby performing a position detection and baking of the conductive paste in a range corresponding to the application angle of the laser light to the conductive paste.

In the conductive substrate, a laser light source of the first laser light and the second laser light is preferably a common light source.

A laser light source of the first laser light and the second laser light is a common light source, and thereby laser light emitted from the same laser light source is output as the first laser light and the second laser light.

In the conductive substrate, a laser light source of the first laser light, the second laser light, and the third laser light is preferably a common light source.

A laser light source of the first laser light, the second laser light, and the third laser light is a common light source, and thereby laser light emitted from the same laser light source is output as the first laser light, the second laser light, and the third laser light.

According to another embodiment, there is provided a manufacturing method of a conductive substrate including coating a conductive paste at a predetermined position of a substrate which is made of a resin material; detecting a position of the conductive paste on the substrate based on a difference in reflectance depending on the application positions of first laser light applied to the substrate; and baking the conductive paste by applying second laser light to the conductive paste of which a position on the substrate is detected, thereby forming a conductive layer on the substrate.

Therefore, the second laser light having a light amount necessary for baking is applied only to the conductive paste on the substrate.

In the manufacturing method of the conductive substrate, a formation state of the conductive layer on the substrate is preferably detected by applying the third laser light to the substrate.

A formation state of the conductive layer on the substrate is detected by applying third laser light to the substrate, and thereby it is possible to change a light amount of the second laser light according to the formation state of the conductive layer.

In the manufacturing method of the conductive substrate, an application intensity of the second laser light to the conductive paste is preferably varied according to an application time.

By varying the application intensity of the second laser light to the conductive paste according to an application time, it is possible to vary the application intensity of laser light depending on an absorption state of heat of the conductive paste according to the application time of the laser light.

In the manufacturing method of the conductive substrate, it is preferable that the substrate be moved in a predetermined direction, a position of the conductive paste be detected by varying the application angle of the first laser light to the substrate in a direction perpendicular to the movement direction of the substrate, and the conductive paste be baked by varying the application angle of the second laser light to the substrate in the direction perpendicular to the movement direction of the substrate.

A position of the conductive paste is detected by varying the application angle of the first laser light to the substrate, and the conductive paste is baked by varying the application angle of the second laser light to the substrate, thereby performing a position detection and baking of the conductive paste in a range corresponding to the application angle of the laser light to the conductive paste.

In the manufacturing method of the conductive substrate, a laser light source of the first laser light and the second laser light is preferably a common light source.

A laser light source of the first laser light and the second laser light is a common light source, and thereby laser light emitted from the same laser light source is output as the first laser light and the second laser light.

In the manufacturing method of the conductive substrate, a laser light source of the first laser light, the second laser light, and the third laser light is preferably a common light source.

A laser light source of the first laser light, the second laser light, and the third laser light is a common light source, and thereby laser light emitted from the same laser light source is output as the first laser light, the second laser light, and the third laser light.

According to still another embodiment of the present disclosure, there is provided a laser light irradiation device including a first optical system that applies first laser light to a substrate, made of a resin material, on which a conductive paste is coated at a predetermined position, and detects a position of the conductive paste on the substrate based on a difference in reflectance depending on the application positions; and a second optical system that bakes the conductive paste by applying second laser light to the conductive paste of which a position on the substrate is detected, thereby forming a conductive layer.

Therefore, the second laser light having a light amount necessary for baking is applied only to the conductive paste on the substrate.

The laser light irradiation device preferably further includes a third optical system that detects a formation state of the conductive layer on the substrate by applying third laser light to the substrate.

By providing the third optical system that detects a formation state of the conductive layer on the substrate by applying the third laser light to the substrate, it is possible to change a light amount of the second laser light according to the formation state of the conductive layer.

According to the embodiment of the present disclosure, there is provided a conductive substrate including a substrate made of a resin material; and a conductive layer formed on the substrate by baking a conductive paste which is coated on the substrate at a predetermined position, wherein the conductive layer is formed through baking by applying second laser light to the conductive paste of which a position on the substrate is detected based on a difference in reflectance depending on the application positions of first laser light applied to the substrate.

Therefore, it is possible to use materials having low heat resistance for the substrate, and to improve a degree of freedom of selection regarding materials of the substrate.

According to the embodiment of the present disclosure, a formation state of the conductive layer on the substrate is detected by applying third laser light to the substrate.

Therefore, it is possible to manufacture a conductive substrate having high operation reliability through stabilization of a baking state.

According to the embodiment of the present disclosure, an application intensity of the second laser light to the conductive paste is varied according to an application time.

Therefore, with respect to a conductive paste where a heat absorption state is varied according to an application time of laser light, it is possible to secure an optimal baking state of the conductive paste in consideration of a heat absorption amount and to form a conductive layer having favorable conductivity.

According to the embodiment of the present disclosure, the substrate is moved in a predetermined direction, a position of the conductive paste is detected by varying the application angle of the first laser light to the substrate in a direction perpendicular to the movement direction of the substrate, and the conductive paste is baked by varying the application angle of the second laser light to the substrate in the direction perpendicular to the movement direction of the substrate.

Therefore, it is possible to simply and reliably perform a position detection of the conductive paste to the substrate and application of laser light to the conductive paste based on the application angle of the laser light to the substrate and the movement position of the substrate.

According to the embodiment of the present disclosure, a laser light source of the first laser light and the second laser light is a common light source.

Therefore, it is possible to reduce the number of components and manufacturing costs.

According to the embodiment of the present disclosure, a laser light source of the first laser light, the second laser light, and the third laser light is a common light source.

Therefore, it is possible to further reduce the number of components and the manufacturing costs.

According to the embodiment of the present disclosure, there is provided a manufacturing method of a conductive substrate including coating a conductive paste at a predetermined position of a substrate which is made of a resin material; detecting a position of the conductive paste on the substrate based on a difference in reflectance depending on the application positions of first laser light applied to the substrate; and baking the conductive paste at high temperature by applying second laser light to the conductive paste of which a position on the substrate is detected, thereby forming a conductive layer on the substrate.

Therefore, it is possible to use materials having low heat resistance for the substrate, and to improve a degree of freedom of selection regarding materials of the substrate.

According to the embodiment of the present disclosure, a formation state of the conductive layer on the substrate is detected by applying third laser light to the substrate.

Therefore, it is possible to manufacture a conductive substrate having high operation reliability through stabilization of a baking state.

According to the embodiment of the present disclosure, an application intensity of the second laser light to the conductive paste is varied according to an application time.

Therefore, with respect to a conductive paste where a heat absorption state is varied according to an application time of laser light, it is possible to secure an optimal baking state of the conductive paste in consideration of a heat absorption amount and to form a conductive layer having favorable conductivity.

According to the embodiment of the present disclosure, the substrate is moved in a predetermined direction, a position of the conductive paste is detected by varying the application angle of the first laser light to the substrate in a direction perpendicular to the movement direction of the substrate, and the conductive paste is baked by varying the application angle of the second laser light to the substrate in the direction perpendicular to the movement direction of the substrate.

Therefore, it is possible to simply and reliably perform a position detection of the conductive paste to the substrate and application of laser light to the conductive paste based on the application angle of the laser light to the substrate and the movement position of the substrate.

According to the embodiment of the present disclosure, a laser light source of the first laser light and the second laser light is a common light source.

Therefore, it is possible to reduce the number of components and the manufacturing costs.

According to the embodiment of the present disclosure, a laser light source of the first laser light, the second laser light, and the third laser light is a common light source.

According to the embodiment of the present disclosure, there is provided a laser light irradiation device including a first optical system that applies first laser light to a substrate, made of a resin material, on which a conductive paste is coated at a predetermined position, and detects a position of the conductive paste on the substrate based on a difference in reflectance depending on the application positions; and a second optical system that bakes the conductive paste by applying second laser light to the conductive paste of which a position on the substrate is detected, thereby forming a conductive layer.

Therefore, it is possible to use materials having low heat resistance for the substrate, and to improve a degree of freedom of selection regarding materials of the substrate.

According to the embodiment of the present disclosure, there is further provided a third optical system that detects a formation state of the conductive layer on the substrate by applying third laser light to the substrate.

Therefore, it is possible to manufacture a conductive substrate having high operation reliability through stabilization of a baking state.

Additional features and advantages are described herein, and will be apparent from the following Detailed Description and the figures.

### BRIEF DESCRIPTION OF THE FIGURES

FIG. 1 shows a conductive substrate, a manufacturing method of the conductive substrate, and a laser light irradiation device according to embodiments of the present disclosure along with FIGS. 2 to 6, and this figure is a schematic plan view of the conductive substrate.

FIG. 2 is a conceptual diagram illustrating the laser light irradiation device and the like.

FIG. 3 shows a detailed example when each laser light beam is applied along with FIGS. 4 to 6, and this figure is a graph illustrating a detailed example when the first laser light is applied.

FIG. 4 is a graph illustrating a detailed example when the second laser light is applied.

FIG. 5 is a graph illustrating a detailed example when the third laser light is applied along with a state where the second laser light which is controlled based on a reflected light amount of the third laser light has been adjusted.

FIG. 6 is a graph illustrating an example where a light amount of the second laser light is varied according to time.

### DETAILED DESCRIPTION

Hereinafter, a conductive substrate, a manufacturing method of the conductive substrate, and a laser light irradiation device according to embodiments of the present disclosure will be described with reference to the accompanying drawings.

A conductive substrate, a manufacturing method of the conductive substrate, and a laser light irradiation device according to the embodiments of the present disclosure are applied to a conductive substrate which is manufactured using a printable electronics technique which can achieve a decrease in environmental burdens and low costs by forming fine conductive patterns (conductive layers) through printing, a manufacturing method of the conductive substrate, and a laser light irradiation device.

The conductive substrate manufactured using the printable electronics technique is applied to a flat panel display such as, for example, a liquid crystal display, a plasma display, or an organic electroluminescence display.

Although, in the following, a direction is described in a state where a substrate functioning as a printed object provided with conductive layers is disposed in a direction facing the vertical direction, the embodiments of the present disclosure are not limited to such a direction.

### Configuration of Conductive Substrate

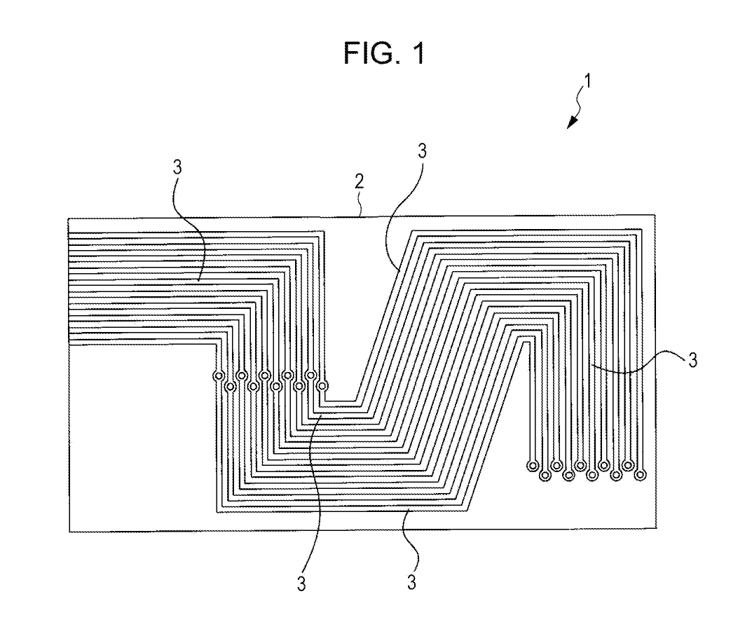

A conductive substrate 1, as shown in FIG. 1, includes a substrate 2 functioning as a printed object, and conductive layers 3, 3, . . . formed on the substrate 2, and the conductive layers 3, 3, . . . function as conductive patterns.

The substrate 2 is formed using a resin material, for example, polyethylene terephthalate, polyimide, or the like.

The conductive layers 3, 3, . . . are formed by baking a conductive paste, for example, a metal paste coated on the substrate 2 with laser light applied by a laser light irradiation device described later, and use, for example, a silver nanoink. As a material of the conductive layers 3, 3, . . . , for example, gold, copper, nickel, tin, lead, and the like may be used. In addition, the conductive paste is not limited to the metal paste, and, for example, an organic conductive paste or a conductive polymer may be used as the conductive paste.

Configuration of Laser Light Irradiation Device and the like and Manufacturing Method of Conductive Substrate

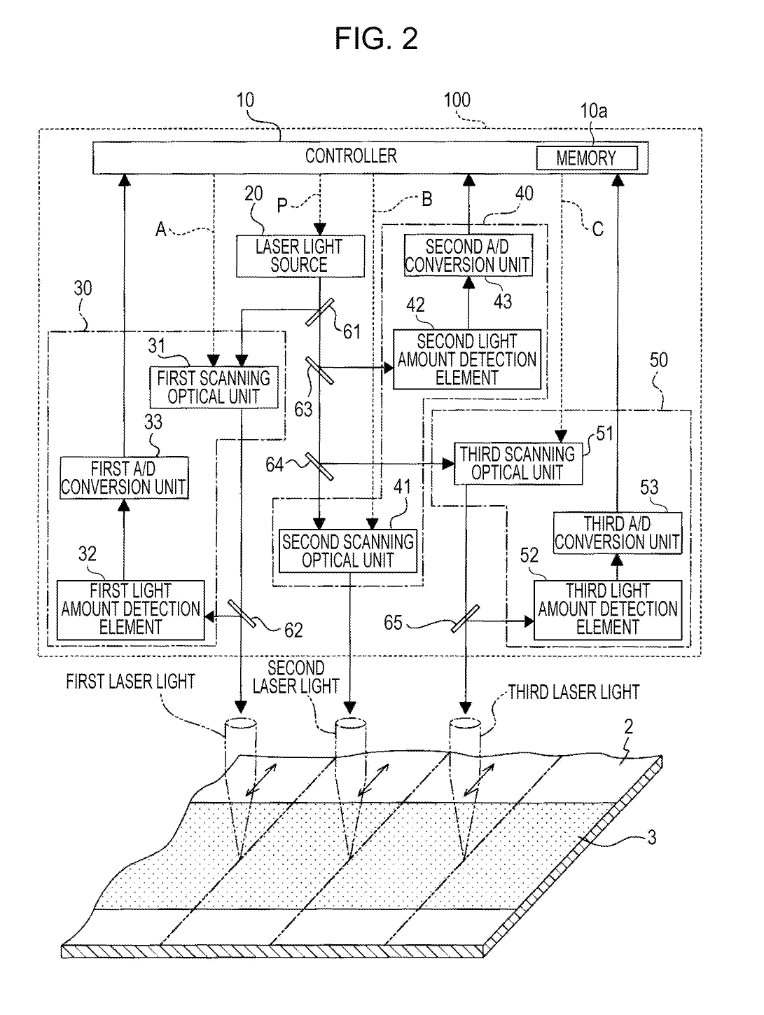

A laser light irradiation device 100 includes a controller 10, a laser light source 20, a first optical system 30, a second optical system 40, and a third optical system 50 (refer to FIG. 2).

The substrate 2 where a conductive paste is coated at a predetermined position is disposed on the lower side of the laser light irradiation device 100, and the substrate 2 is moved by a movement mechanism (not shown) in a predetermined direction, for example, from the left side to the right side.

The controller 10 has a function of controlling the overall laser light irradiation device 100, and sends various commands to the laser light source 20, the first optical system 30, the second optical system 40, and the third optical system 50. The controller 10 has a memory 10a which stores a variety of information.

The laser light source 20 is, for example, a semiconductor laser, and emits laser light of, for example, 300 nm to 600 nm to the substrate 2 based on an output command P from the controller 10.

The first optical system 30 includes a first scanning optical unit 31, a first light amount detection element 32, and a first A/D conversion unit 33.

A transflective mirror 61 which reflects or transmit laser light is disposed between the laser light source 20 and the first scanning optical unit 31, and a transflective mirror 62 which reflects or transmits laser light is disposed between the first scanning optical unit 31 and the first light amount detection element 32.

The first scanning optical unit 31 has, for example, a polygon mirror, and, based on a scanning command A from the controller 10, irradiates the substrate 2 with first laser light which is emitted from the laser light source 20, is reflected by the transflective mirror 61, and is transmitted through the transflective mirror 62 so as to be scanned in a predetermined angle range. The substrate 2 is scanned with the first laser light applied from the first scanning optical unit 31 in the front and rear direction, and reflected light of the first laser light which is reflected during the scanning of the substrate 2 is reflected by the transflective mirror 62 and then is incident to the first light amount detection element 32.

At this time, due to a difference in reflectance depending on irradiated positions of the first laser light, reflected light having a large light amount which is reflected from the conductive paste coated on the substrate 2 and reflected light having a small light amount which is reflected from a part where the conductive paste does not exist on the substrate 2 are incident to the first light amount detection element 32. A light amount of the incident reflected light is detected by the first light amount detection element 32, and a detection value of the light amount is sent to the first A/D conversion unit 33.

The detection value of the light amount for the reflected light sent to the first A/D conversion unit 33 is converted into a digital value by the first A/D conversion unit 33, and then the converted detection signal is sent to the controller 10.

The controller 10 detects (calculates) a position of the conductive paste on the substrate 2 based on an application angle (scanning angle) of the laser light to the substrate 2 and the detection signal sent from the first A/D conversion unit 33, and the detected positional information of the conductive paste is stored in the memory 10a.

The second optical system 40 includes a second scanning optical unit 41, a second light amount detection element 42, and a second A/D conversion unit 43.

Transflective mirrors 63 and 64 which reflect or transmit laser light are sequentially disposed from the transflective mirror 61 side between the transflective mirror 61 and the second scanning optical unit 41.

The second scanning optical unit 41 has, for example, a polygon mirror, and, based on a scanning modulation command B from the controller 10, irradiates the substrate 2 with second laser light which is emitted from the laser light source 20, is sequentially transmitted through the transflective mirrors 61, 63 and 64 and is modulated so as to be scanned in a predetermined angle range. An applied position of the second laser light to the substrate 2 is located at the movement direction of the substrate 2 as compared with an applied position of the first laser light to the substrate 2.

At this time, the controller 10 reads the positional information of the conductive paste detected through the first laser light irradiation from the memory 10a, and the second laser light having a light amount necessary for baking is applied only to the conductive paste based on the positional information. Therefore, the part where the conductive paste on the substrate 2 does not exist is not irradiated with the second laser light, or is irradiated with the second laser light having a light amount smaller than the light amount necessary for baking. The second laser light is applied to the conductive paste, the conductive paste is backed so as to form the conductive layers 3, 3, . . . .

When the second laser light is applied to the conductive paste, reflected light of the second laser light is transmitted through the transflective mirror 64, is reflected by the transflective mirror 63, and is incident to the second light amount detection element 42.

A light amount of the incident reflected light is detected by the second light amount detection element 42, and a detection value of the light amount is sent to the second A/D conversion unit 43.

The detection value of the light amount for the reflected light sent to the second A/D conversion unit 43 is converted into a digital value by the second A/D conversion unit 43, and then the converted detection signal is sent to the controller 10.

The controller 10 detects an output of the laser light emitted from the laser light source 20 based on the detection signal sent from the second A/D conversion unit 43, and adjusts an output of the laser light emitted from the laser light source 20, necessary for baking of the conductive paste based on the detected output.

The third optical system 50 includes a third scanning optical unit 51, a third light amount detection element 52, and a third A/D conversion unit 53.

A transflective mirror 65 which reflects or transmits laser light is disposed between the third scanning optical unit 51 and the third light amount detection element 52.

The third scanning optical unit 51 has, for example, a polygon mirror, and, based on a scanning command C from the controller 10, irradiates the substrate 2 with third laser light which is emitted from the laser light source 20, is sequentially transmitted through the transflective mirrors 61 and 63, is reflected by the transflective mirror 64, and is transmitted through the transflective mirror 65 in a predetermined angle range. An applied position of the third laser light to the substrate 2 is located at the movement direction of the substrate 2 as compared with an applied position of the second laser light to the substrate 2. The substrate 2 is scanned with the third laser light applied from the third scanning optical unit 51 in the front and rear direction, and reflected light of the third laser light which is reflected during the scanning of the substrate 2 is reflected by the transflective mirror 65 and then is incident to the third light amount detection element 52.

At this time, reflected light of which a light amount is varied depending on a state where the conductive paste is formed is incident to the third light amount detection element 52. A light amount of the incident reflected light is detected by the third light amount detection element 52, and a detection value of the light amount is sent to the third A/D conversion unit 53.

The detection value of the light amount for the reflected light sent to the third A/D conversion unit 53 is converted into a digital value by the third A/D conversion unit 53, and then the converted detection signal is sent to the controller 10.

The controller 10 controls an output of the laser light source 20 such that a reflected light amount when the third laser light is applied becomes a light amount necessary for baking the conductive paste based on an application angle (scanning angle) of the third laser light and the detection signal sent from the third A/D conversion unit 53, thereby adjusting a light amount of the second laser light applied to the conductive paste.

In addition, although an example where the laser light irradiation device 100 is provided with the first optical system 30, the second optical system 40, and the third optical system 50 has been described in the above description, for example, the laser light irradiation device may be a so-called multi-head which has a plurality of sets, each set having the first optical system 30, the second optical system 40, and the third optical system 50.

If the multi-head is provided, it is possible to improve productivity of the conductive substrate 1 since a plurality of substrates 2, 2, . . . are irradiated with laser light together.

Detailed Example when Each Laser Light Beam is Applied

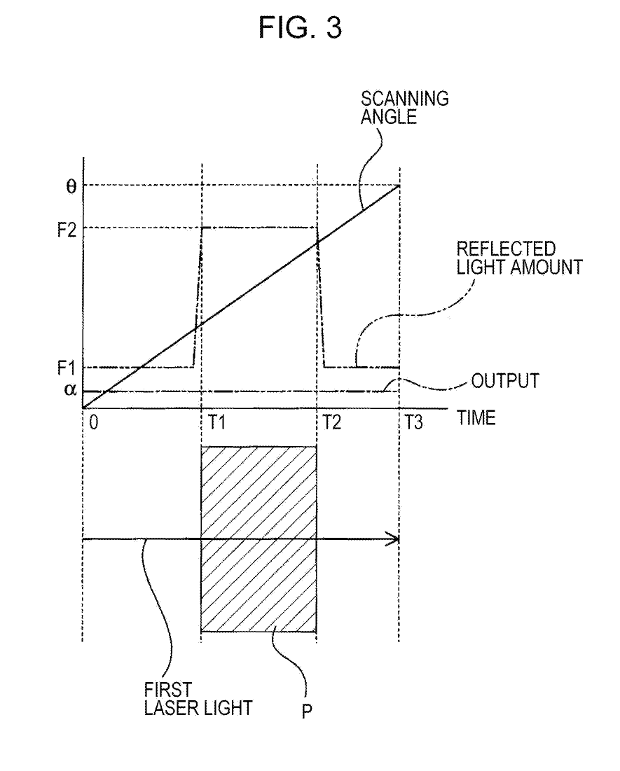

Hereinafter, a detailed example when each laser light beam is applied will be described with reference to each graph (refer to FIGS. 3 to 6).

First, a detailed example when the first laser light is applied will be described (refer to FIG. 3).

In FIG. 3, the transverse axis expresses an application time of the first laser light, and the longitudinal axis expresses a scanning angle (solid line) of the first laser light to the substrate 2, an output (one dot chain line) of the first laser light, and a reflected light amount of the first laser light (two-dot chain line).

The example shown in FIG. 3 indicates a state where the first laser light is scanned at an application angle of 0° to θ from the time 0 to the time T3, and the conductive paste P is detected between the time T1 and the time T2. An output (light amount) of the first laser light is a constant value α, and a reflected light amount is a small light amount F1 at a position where the conductive paste P does not exist, and is a large light amount F2 at a position where the conductive paste P exists.

As such, the first laser light functions as laser light for detecting a position of the conductive paste P on the substrate 2 based on a difference in the reflectance depending on the applied positions through the scanning of the substrate 2.

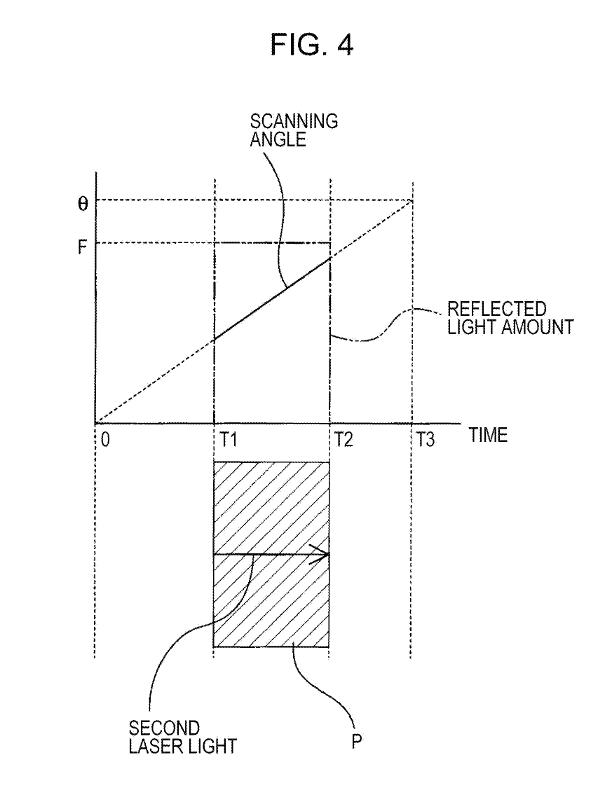

Next, a detailed example when the second laser light is applied will be described (refer to FIG. 4).

In FIG. 4, the transverse axis expresses an application time of the second laser light, and the longitudinal axis expresses a scanning angle (solid line) of the second laser light to the substrate 2, and an output (one dot chain line) of the second laser light.

The example shown in FIG. 4 indicates a state where the conductive paste P is scanned with the second laser light from the time T1 to the time T2, and the second laser light is applied to the conductive paste P between the time T1 and the time T2. An output (light amount) of the second laser light is a light amount of 0 at a position where the conductive paste P does not exist, and is a large light amount F at a position where the conductive paste P exists.

As such, the second laser light functions as laser light for being applied to the conductive paste P of which the position is detected through the application of the first laser light and detecting the conductive layers 3, 3, . . . at high temperature.

A light amount of the second laser light is adjusted in real time by a control for maintaining an optimal baking state of the conductive paste P through the application of the third laser light in addition to a feedback control for stabilizing an output caused by a temperature variation due to emission of the laser light from the laser light source 20.

In addition, although the example where the light amount is 0 between the time 0 and the time T1 and the time T2 and the time T3 has been described in the above description, there may be an application of the second laser light having a light amount smaller than the light amount F which does not damage the substrate 2 at the time intervals.

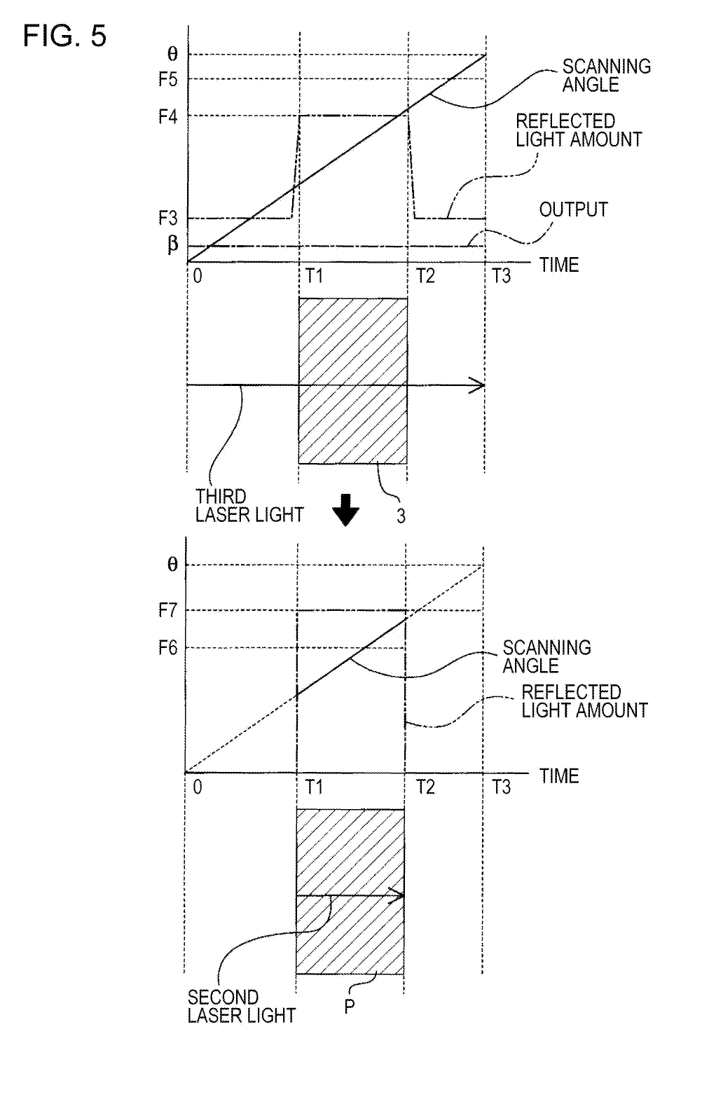

Next, a detailed example when the third laser light is applied will be described (refer to the upper part of FIG. 5).

In the upper part of FIG. 5, the transverse axis expresses an application time of the third laser light, and the longitudinal axis expresses a scanning angle (solid line) of the third laser light to the substrate 2, an output (one dot chain line) of the third laser light, and a reflected light amount of the third laser light (two-dot chain line).

The example shown in the upper part of FIG. 5 indicates a state where the third laser light is scanned at an application angle of 0° to θ from the time 0 to the time T3, and the third laser light is applied to the conductive layer 3 between the time T1 and the time T2. An output (light amount) of the third laser light is a constant value β, and a reflected light amount is a small light amount F3 at a position where the conductive layer 3 does not exist, and is a large light amount F4 at a position where the conductive layer 3 exists. At this time, when the conductive layer 3 is formed in an optimal state, a light amount of the reflected light is recognized as the light amount F5 in advance.

A reflected light amount when the third laser light is applied to the conductive layers 3, 3, . . . formed by baking the conductive paste P is lower than a reflected light amount obtained when an optimal baking state is secured through insufficient decomposition of dispersants contained in the conductive paste P. Therefore, the example shown in the upper part of FIG. 5 corresponds to a case where the conductive layer 3 is not formed in an optimal state.

Accordingly, a reflected light amount obtained when an optimal baking state is secured is set as a reference light amount in advance, and a difference between a reflected light amount obtained when the third laser light is applied and the reference light amount is added to the second laser light when subsequent baking is performed as a correction value, thereby adjusting a light amount of the second laser light.

This control is performed for the entire substrate 2 in real time, thereby forming conductive layers 3, 3, . . . which have small imbalance in a baking state of the conductive pastes P, P, . . . on the entire substrate 2 and have favorable conductivity.

The lower part of FIG. 5 shows an example indicating a state where the second laser light has been adjusted when the above-described control is performed. The second laser light has a light amount of F6 to F7 so as to be increased in an output after being adjusted.

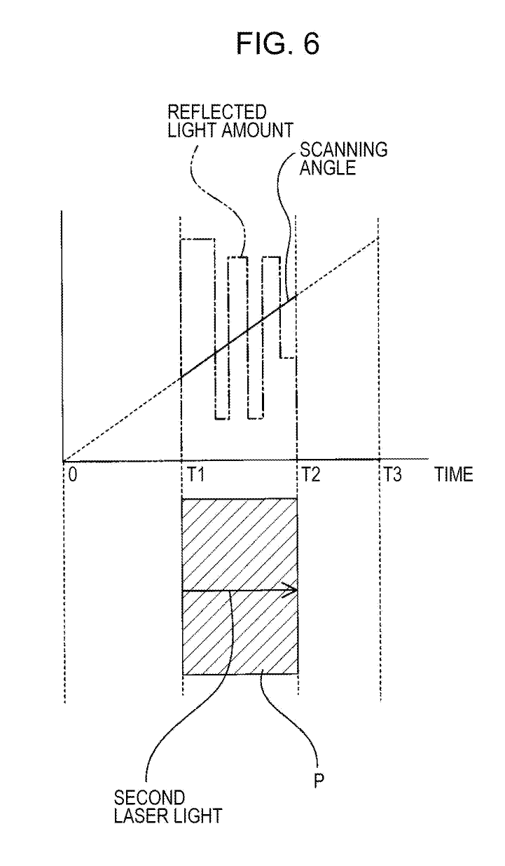

In addition, the second laser light can vary application intensity (light amount) according to an application time, as shown in FIG. 6, in a state of being applied to the conductive paste P. For example, a light amount like the light amount which is applied to the conductive paste P and secures an optimal baking state between the time T1 and the time T2 may be applied to the conductive paste P in a state where a light amount is varied according to time.

When laser light is applied to the conductive paste P, an absorption state of heat may be varied according to elapsed time due to metal particles or a material of the substrate 2, and thus, typically, an absorption rate of heat is low immediately after the laser light is applied.

Therefore, by performing the control for varying a light amount of the second laser light according to time as above, it is possible to secure an optimal baking state of the conductive paste P in consideration of an absorption amount of heat which is varied according to elapsed time and to form the conductive layers 3, 3, . . . having favorable conductivity.

### Conclusion

As described above, in the conductive substrate 1, the conductive layers 3, 3, . . . are formed through baking by applying the second laser light to a conductive paste of which a position on the substrate 2 is detected based on a difference in reflectance depending on applied positions through an application of the first laser light.

Therefore, since the second laser light having a light amount necessary for baking is applied only to the conductive paste on the substrate 2, it is possible to use a material having low heat resistance for the substrate 2, to improve a degree of freedom of selection regarding a material of the substrate 2, and to reduce manufacturing costs.

In addition, since the third laser light is applied to the substrate 2 and thereby a state where the conductive layers 3, 3, . . . on the substrate 2 are formed is detected, it is possible to manufacture the conductive substrate 1 having high operation reliability through stabilization of a baking state.

Further, the substrate 2 is moved in a predetermined direction, and application angles of the first laser light and the second laser light are varied and scanned in a direction perpendicular to the movement direction of the substrate 2. Therefore, it is possible to simply and reliably perform a position detection of the conductive paste to the substrate 2 and application of laser light to the conductive paste based on the application angle of the laser light to the substrate 2 and the movement position of the substrate 2.

Further, the first laser light and the second laser light uses the laser light source 20 as a common light source, and thus it is possible to reduce the number of components and manufacturing costs.

In addition, the third laser light uses the laser light source 20 as a light source common to the first laser light and the second laser light, and thus it is possible to further reduce the number of components and the manufacturing costs.

### Others

As described above, the conductive substrate 1 manufactured according to the embodiment of the present disclosure is applied to a flat panel display or the like such as a liquid crystal display, a plasma display, or an organic electroluminescence display.

The present disclosure may be applied to other fields, for example, to a field of electronic paper having semiconductor circuits formed through printing, a memory device having a capacitor structure formed through printing, an antenna device formed through printing, and a dye-sensitized solar cell having wirings formed through printing.

Further, the present disclosure may be applied to a flexible display field where wires are formed on a plastic substrate using silver nanoink, or gate insulating layers or polymer insulating layers are formed using pentacene.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A conductive substrate comprising:
a substrate made of a resin material; and
a conductive layer formed on the substrate by baking a conductive paste which is coated on the substrate at a predetermined position,
wherein the conductive layer is formed through baking by applying second laser light to the conductive paste of which a position on the substrate is detected based on a difference in reflectance depending on application positions of first laser light applied to the substrate.

2. The conductive substrate according to claim 1, wherein a formation state of the conductive layer on the substrate is detected by applying third laser light to the substrate.

3. The conductive substrate according to claim 1, wherein application intensity of the second laser light to the conductive paste is varied according to an application time.

4. The conductive substrate according to claim 1, wherein the substrate is moved in a predetermined direction,
wherein a position of the conductive paste is detected by varying an application angle of the first laser light to the substrate in a direction perpendicular to the movement direction of the substrate, and
wherein the conductive paste is baked by varying an application angle of the second laser light to the substrate in the direction perpendicular to the movement direction of the substrate.

5. The conductive substrate according to claim 1, wherein a laser light source of the first laser light and the second laser light is a common light source.

6. The conductive substrate according to claim 2, wherein a laser light source of the first laser light, the second laser light, and the third laser light is a common light source.

7. A manufacturing method of a conductive substrate comprising:
coating a conductive paste at a predetermined position of a substrate which is made of a resin material;
detecting a position of the conductive paste on the substrate based on a difference in reflectance depending on application positions of first laser light applied to the substrate; and
baking the conductive paste by applying second laser light to the conductive paste of which a position on the substrate is detected, thereby forming a conductive layer on the substrate.

8. The manufacturing method of the conductive substrate according to claim 7, wherein a formation state of the conductive layer on the substrate is detected by applying third laser light to the substrate.

9. The manufacturing method of the conductive substrate according to claim 7, wherein application intensity of the second laser light to the conductive paste is varied according to an application time.

10. The manufacturing method of the conductive substrate according to claim 7, wherein the substrate is moved in a predetermined direction,
wherein a position of the conductive paste is detected by varying an application angle of the first laser light to the substrate in a direction perpendicular to the movement direction of the substrate, and
wherein the conductive paste is baked by varying an application angle of the second laser light to the substrate in the direction perpendicular to the movement direction of the substrate.

11. The manufacturing method of the conductive substrate according to claim 7, wherein a laser light source of the first laser light and the second laser light is a common light source.

12. The manufacturing method of the conductive substrate according to claim 8, wherein a laser light source of the first laser light, the second laser light, and the third laser light is a common light source.

13. A laser light irradiation device comprising:
a first optical system that applies first laser light to a substrate, made of a resin material, on which a conductive paste is coated at a predetermined position, and detects a position of the conductive paste on the substrate based on a difference in reflectance depending on application positions; and
a second optical system that bakes the conductive paste by applying second laser light to the conductive paste of which a position on the substrate is detected, thereby forming a conductive layer.

14. The laser light irradiation device according to claim 13 further comprising a third optical system that detects a formation state of the conductive layer on the substrate by applying third laser light to the substrate.
